(19) United States
(12) Patent Application Publication
(10) Pub. No.: US 2023/0296690 A1
(43) Pub. Date: Sep. 21, 2023

(54) Battery System and Detection Method

(71) Applicant: Prime Planet Energy & Solutions, Inc., Tokyo (JP)

(72) Inventor: Junya YANO, Kato-shi (JP)

(21) Appl. No.: 18/183,956

(22) Filed: Mar. 15, 2023

(30) Foreign Application Priority Data
Mar. 18, 2022 (JP) 2022-043741

(51) Int. Cl. G01R 31/392; H01M 10/42; H01M 10/48

(52) U.S. Cl. CPC G01R 31/392; H01M 10/425; H01M 10/48

(57) ABSTRACT

A battery system includes: an battery assembly; a controller; and a voltage sensor, a first temperature sensor, and a second temperature sensor, which are a plurality of sensors that each detects a parameter of the battery. An abnormality of a sensor of the plurality of sensors does not lead to an abnormality of a remainder of the sensors. The controller determines that the battery assembly is abnormal when at least two sensors of the plurality of sensors output abnormal values.

This nonprovisional application is based on Japanese Patent Application No. 2022-043741 filed on Mar. 18, 2022 with the Japan Patent Office, the entire contents of which are hereby incorporated by reference.

### BACKGROUND OF THE INVENTION

### Field of the Invention

The present disclosure relates to a battery system and a detection method.

### Description of the Background Art

For example, Japanese Patent Laying-Open No. 2020-145841 discloses a battery and a sensor that measures a physical quantity of the battery. In the technology described in Japanese Patent Laying-Open No. 2020-145841, presence or absence of an abnormality of the battery is determined based on the physical quantity measured by the sensor. Also, Japanese Patent Laying-Open No. 2020-145841 discloses a method of diagnosing a failure of the sensor.

### SUMMARY OF THE INVENTION

It has been desired to improve accuracy in detecting an abnormality of a battery.

The present disclosure has been made to solve the above-described problem and has an object to provide a technology for improving accuracy in detecting an abnormality of a battery.

A battery system according to the present disclosure includes: a battery; a plurality of sensors that each detect a parameter of the battery; and a controller. An abnormality of a sensor of the plurality of sensors does not lead to an abnormality of a remainder of the sensors. The controller determines that the battery is abnormal when at least two sensors of the plurality of sensors output abnormal values.

A detection method of the present disclosure is a detection method for detecting an abnormality of a battery system. The battery system includes a battery, and a plurality of sensors that each detect a parameter of the battery. An abnormality of a sensor of the plurality of sensors does not lead to an abnormality of a remainder of the sensors. The detection method includes determining that the battery is abnormal when at least two sensors of the plurality of sensors output abnormal values.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing an exemplary configuration of a battery system according to the present embodiment.

FIG. 2 is a diagram showing a battery assembly, a controller, and the like.

FIG. 3 is a functional block diagram of the controller.

FIG. 4 is a flowchart showing a process by the controller.

FIG. 5 is a diagram showing the battery assembly, the controller, and the like.

### DESCRIPTION OF THE PREFERRED EMBODIMENTS

Hereinafter, embodiments of the present disclosure will be described in detail with reference to figures. It should be noted that in the figures, the same or corresponding portions are denoted by the same reference characters, and will not be described repeatedly.

### [Present Embodiment]

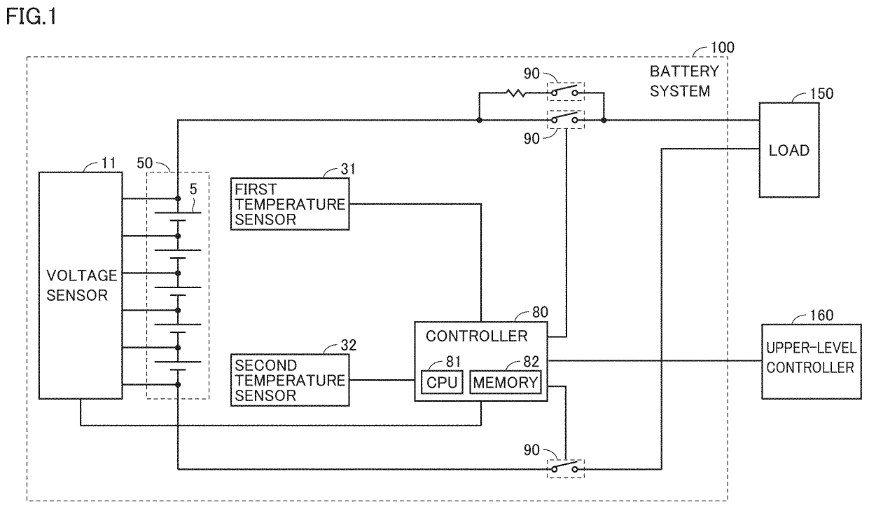

FIG. 1 is a diagram showing an exemplary configuration of a battery system 100 according to the present embodiment. Battery system 100 includes a battery assembly 50, a plurality of sensors, a controller 80, and one or more relays 90. The plurality of sensors are constituted of a voltage sensor 11, a first temperature sensor 31, and a second temperature sensor 32.

In the example of FIG. 1, battery system 100 has three relays 90. One end of each relay 90 is connected to a load 150. The other end of each relay 90 is connected to battery assembly 50. Controller 80 is connected to an upper-level controller 160.

Battery assembly 50 is constituted of one or more unit batteries 5 (cells). In the example of FIG. 1, battery assembly 50 is constituted of one or more unit batteries 5 connected in series. Battery assembly 50 corresponds to “battery” of the present disclosure.

Voltage sensor 11 detects a voltage value of each of one or more unit batteries 5 of battery assembly 50. First temperature sensor 31 detects a temperature of a first portion of battery assembly 50. Second temperature sensor 32 detects a temperature of a second portion of battery assembly 50. The voltage value, the temperature of the first portion, and the temperature of the second portion are output to controller 80. The temperature of the first portion is also referred to as “first temperature” and the temperature of the second portion is also referred to as “second temperature”.

Each of the voltage value, the first temperature, and the second temperature correspond to “parameter” of the present disclosure. Thus, each of the plurality of sensors (in the present embodiment, voltage sensor 11, first temperature sensor 31, and second temperature sensor 32) detects a parameter of battery assembly 50. Controller 80 performs a predetermined process using this parameter. Examples of the predetermined process include: a process of calculating an impedance of unit battery 5; and the like.

Voltage sensor 11, first temperature sensor 31, and second temperature sensor 32 are disposed to be independent of each other. Here, the term “independent” means that a failure of a sensor of the plurality of sensors does not lead to a failure of a remainder of the sensors. The “failure” will be described later. The term “failure of a sensor” is also referred to as “abnormality of a sensor”.

In the present embodiment, a failure of voltage sensor 11 does not lead to failures of first temperature sensor 31 and second temperature sensor 32. Further, a failure of first temperature sensor 31 does not lead to failures of voltage sensor 11 and second temperature sensor 32. A failure of second temperature sensor 32 does not lead to failures of voltage sensor 11 and first temperature sensor 31.

An exemplary method of making the sensors independent of one another is to accommodate detection devices (detection elements) of the sensors in individual housings. For example, thermistors, i.e., detection devices, of first temperature sensor 31 and second temperature sensor 32 are accommodated in different housings. It should be noted that a plurality of individual voltage sensors (not shown) are accommodated in one housing as voltage sensor 11 as described above. Each of the individual voltage sensors measures a voltage of one unit battery 5. Therefore, in the present embodiment, the plurality of individual voltage sensors can be dependent on one another.

As described later, controller 80 detects an abnormality of unit battery 5 and a failure of voltage sensor 11 based on the voltage value, the first temperature, and the second temperature. The abnormality of unit battery 5 is, for example, an excessive increase in temperature of unit battery 5. Further, the abnormality of unit battery 5 may include propagation of heat, which results from the excessive increase in temperature of unit battery 5, to another unit battery.

Further, controller 80 transmits a control signal to relay 90. The control signal is a signal for turning on relay 90 (closing relay 90) and turning off relay 90 (opening relay 90). Further, controller 80 transmits a notification signal to upper-level controller 160.

Controller 80 has a CPU (central processing unit) 81 and a memory 82 as main components. Memory 82 has, for example, a ROM (Read Only Memory) and a RAM (Random Access Memory). The ROM stores a program to be executed by CPU 81. The RAM temporarily stores data generated by execution of the program by CPU 81. Controller 80 is also referred to as “control circuit”.

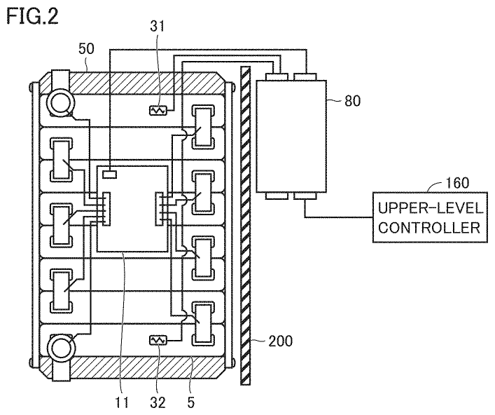

FIG. 2 is a diagram showing battery assembly 50, controller 80, and the like. As described above, as the abnormality of unit battery 5, the temperature of unit battery 5 can be increased excessively. Such an increase in temperature may cause damage of controller 80. To address this, in the present embodiment, controller 80 is disposed at a position to reduce an influence of a battery abnormality (for example, the increase in temperature of unit battery 5) on controller 80. In the example of FIG. 2, a reduction member is provided between battery assembly 50 and controller 80 to reduce the influence. In the example of FIG. 2, the reduction member is a protection wall 200. A material of protection wall 200 is, for example, a high flame-retardant resin and preferably has a grade of V-0 or higher based on the UL94 standard. Since such a protection wall 200 is provided, the influence of the abnormality of unit battery 5 on controller 80 can be reduced.

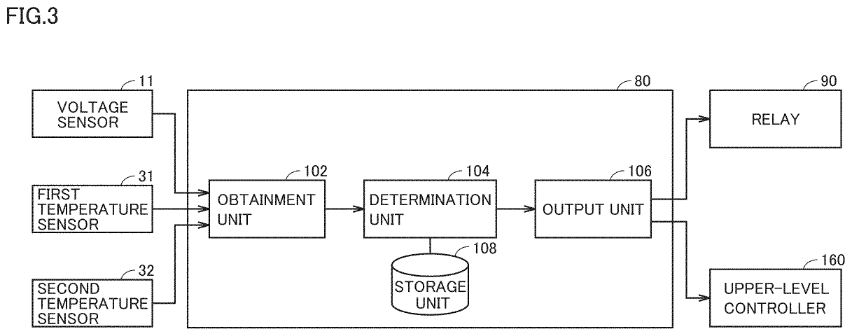

FIG. 3 is a functional block diagram of controller 80. Controller 80 has an obtainment unit 102, a determination unit 104, an output unit 106, and a storage unit 108. Obtainment unit 102 obtains the voltage value from voltage sensor 11, the first temperature from first temperature sensor 31, and the second temperature from second temperature sensor 32.

The voltage value, the first temperature, and the second temperature obtained by obtainment unit 102 are output to determination unit 104. Determination unit 104 detects an abnormality of battery assembly 50 and a failure of voltage sensor 11 based on the voltage value, the first temperature, and the second temperature.

Here, the abnormality of battery assembly 50 and the failure of voltage sensor 11 will be described. A normal range and an abnormal range are defined for each of the voltage value, the first temperature, and the second temperature. The normal range and the abnormal range for each of the voltage value, the first temperature, and the second temperature are stored in storage unit 108. The voltage value, the first temperature, and the second temperature belonging to the respective abnormal ranges are also referred to as “abnormal values”. The voltage value, the first temperature, and the second temperature belonging to the respective normal ranges are also referred to as “normal values”.

Also, voltage sensor 11 may be failed. Here, the “failure of voltage sensor 11” means that voltage sensor 11 outputs an abnormal value even though battery assembly 50 is normal (no abnormality of battery assembly 50 has occurred). Examples of a cause of the failure of voltage sensor 11 include wire disconnection, wear, deterioration, and the like in voltage sensor 11.

Here, situations in which the voltage sensor outputs an abnormal value include the following first situation and second situation. The first situation is such a situation that voltage sensor 11 outputs an abnormal value because an abnormality of battery assembly 50 has occurred. The second situation is such a condition that because voltage sensor 11 is failed even though battery assembly 50 is normal (even though no abnormality of battery assembly 50 has occurred), failed voltage sensor 11 outputs an abnormal value.

In the case of the first situation, i.e., in the case of occurrence of an abnormality of battery assembly 50, battery system 100 preferably performs emergency stop of the output of battery assembly 50. However, in the second situation, no abnormality of battery assembly 50 has occurred, so that battery system 100 does not need to perform the emergency stop.

In a battery system of a comparative example (for example, the battery system of Japanese Patent Laying-Open No. 2020-145841), when a voltage sensor outputs an abnormal value, it is determined that an abnormality of a battery assembly has occurred irrespective of whether or not the situation is the first situation or the second situation. Therefore, in the battery system of the comparative example, the abnormality of the battery assembly is detected even when the situation is the second situation. Thus, accuracy in detecting a battery abnormality is low in the battery system of the comparative example. Therefore, in the battery system of the comparative example, the emergency stop is performed unnecessarily.

To address this, in battery system 100 of the present embodiment, accuracy in detecting an abnormality of battery assembly 50 is improved in the following manner. When determination unit 104 determines that voltage sensor 11 outputs an abnormal value, determination unit 104 determines whether or not the parameters detected by the other sensors (i.e., first temperature sensor 31 and second temperature sensor 32) are abnormal values.

When voltage sensor 11 outputs an abnormal value and the other sensors also output abnormal values, an abnormality of battery assembly 50 is highly likely to have occurred (the situation is highly likely to be the first situation described above). Therefore, in this case, controller 80 determines that an abnormality of battery assembly 50 has occurred.

On the other hand, in some cases, voltage sensor 11 outputs an abnormal value but the other sensors does not output abnormal values. In this case, since voltage sensor 11 is highly likely to be failed, controller 80 determines that voltage sensor 11 is failed.

That is, when at least two sensors of the plurality of sensors output abnormal values (when at least one of first temperature sensor 31 and second temperature sensor 32 and voltage sensor 11 output abnormal values), determination unit 104 determines that battery assembly 50 is abnormal (for example, excessive increase in temperature of unit battery 5).

Meanwhile, when one sensor (i.e., voltage sensor 11) of the plurality of sensors outputs an abnormal value, determination unit 104 determines that the one sensor is abnormal (failed).

Battery system 100 performs a process corresponding to a determination result. When the determination result indicates an abnormality of battery assembly 50, battery system 100 performs a first process. The first process includes, for example, at least one of emergency stop of charging or discharging of battery assembly 50 or notification to upper-level controller 160.

Specifically, when the determination result indicates an abnormality of battery assembly 50, output unit 106 outputs a notification signal to upper-level controller 160. The notification signal is a signal indicating that an abnormality of battery assembly 50 has occurred. When receiving the notification signal, upper-level controller 160 performs an emergency stop of a device (for example, a vehicle) on which battery system 100 is mounted. Further, upper-level controller 160 notifies the occurrence of abnormality of battery assembly 50 to a user of the device. Further, output unit 106 turns off all relays 90, thereby causing an emergency stop of charging or discharging of battery assembly 50.

When the determination result indicates a failure of voltage sensor 11, battery system 100 performs a second process. The second process includes suppression of charging or discharging of battery assembly 50, and discarding of the voltage value from voltage sensor 11.

Specifically, when the determination result indicates a failure of voltage sensor 11, controller 80 does not use the voltage value from voltage sensor 11 (i.e., discards the voltage value), and uses the parameters (first temperature and second temperature) from the other sensors (i.e., first temperature sensor 31 and second temperature sensor 32) so as to perform a process regarding battery assembly 50 (for example, a process for calculating an impedance of battery assembly 50). Further, output unit 106 outputs control signal(s) to at least part of all relays 90, thereby suppressing charging or discharging of battery assembly 50.

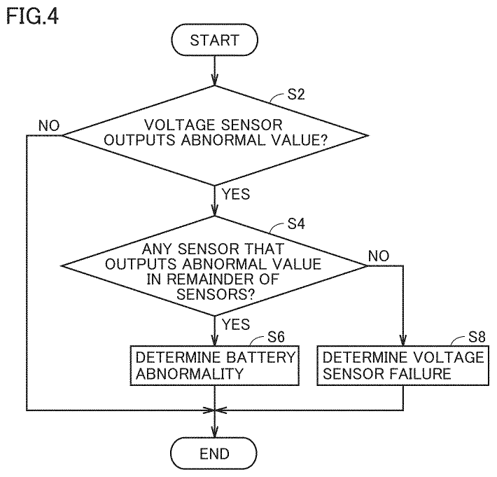

FIG. 4 is a flowchart showing a process of controller 80. The process of FIG. 4 is performed by controller 80 per predetermined period (for example, 0.1 second). In a step S2, controller 80 determines whether or not voltage sensor 11 outputs an abnormal value. When voltage sensor 11 does not output an abnormal value (outputs a normal value) (NO in step S2), the process is ended.

On the other hand, when voltage sensor 11 outputs an abnormal value in step S2 (YES in step S2), the process proceeds to a step S4. In step S4, it is determined whether or not there is a sensor that outputs an abnormal value in a remainder of the sensors (i.e., first temperature sensor 31 and second temperature sensor 32).

When it is determined in step S4 that there is a sensor that outputs an abnormal value in the remainder of the sensors (YES in step S4), controller 80 determines in a step S6 that battery assembly 50 is abnormal. On the other hand, when it is determined in step S4 that there is no sensor that outputs an abnormal value in the remainder of the sensors (NO in step S4), controller 80 determines in step S6 that voltage sensor 11 is abnormal (voltage sensor 11 is failed).

### [Other Embodiments]

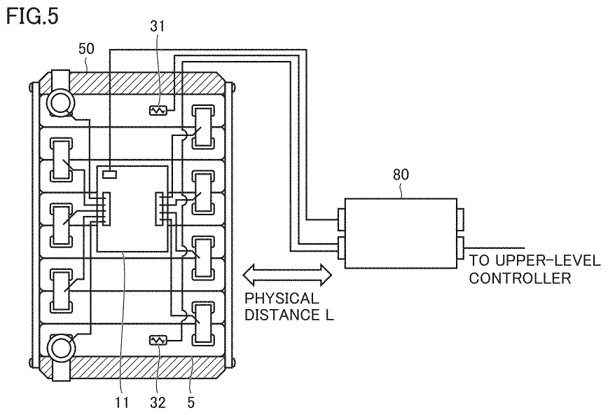

(1) FIG. 5 is a diagram for illustrating another manner of reducing the influence of the abnormality (for example, excessive increase in temperature of unit battery 5) of battery assembly 50 on controller 80. An example shown in FIG. 5 shows a configuration in which a physical distance L between battery assembly 50 and controller 80 is secured instead of providing protection wall 200. Also with the configuration in which battery assembly 50 and controller 80 are separated from each other by physical distance L, the influence of the abnormality of unit battery 5 on controller 80 can be reduced.

Further, protection wall 200 or physical distance L may be configured to protect controller 80 for a first predetermined period of time from secondary damage resulting from an abnormality of battery assembly 50. Here, the first predetermined period time is, for example, a period of time from occurrence of the abnormality of battery assembly 50 to a time at which at least two sensors indicate abnormalities due to the abnormality of battery assembly 50.
(2) In the example of FIG. 4, it has been described that controller 80 is configured to perform the process of step S4 immediately after YES is determined in step S2. However, the process of step S4 may be performed after passage of a second predetermined period of time (for example, several seconds to one hour) from the determination of YES in step S2.
(3) In the above-described example, it has been described that voltage sensor 11 and the temperature sensors are included. However, battery system 100 may include other sensor(s). The other sensor(s) may be, for example, at least one of a current sensor, a pressure sensor, and a gas detection sensor. The current sensor detects a current value of battery assembly 50 as a parameter. The pressure sensor detects an internal pressure of battery assembly 50 (unit battery 5) as a parameter. The gas detection sensor detects a concentration of gas generated from battery assembly 50 or presence or absence of the gas as a parameter.
(4) Hereinafter, a sensor that determines whether or not an abnormal value is output in step S2 is also referred to as “first sensor”, and a sensor that determines whether or not an abnormal value is output in step S4 is also referred to as “second sensor”. In the present embodiment, it is defined that the first sensor is voltage sensor 11, and the second sensor is each of first temperature sensor 31 and second temperature sensor 32. This definition is based on such a premise that “the first sensor is more likely to become abnormal than the second sensor”. That is, it is preferable to define the first sensor and the second sensor based on such a premise.

Although the embodiments of the present invention have been described and illustrated in detail, it is clearly understood that the same is by way of illustration and example only and is not to be taken by way of limitation, the scope of the present invention being interpreted by the terms of the appended claims. The scope of the present invention is defined by the terms of the claims, and is intended to include any modifications within the scope and meaning equivalent to the terms of the claims.

What is claimed is:

1. A battery system comprising:
a battery;
a plurality of sensors that each detect a parameter of the battery; and
a controller, wherein
an abnormality of a sensor of the plurality of sensors does not lead to an abnormality of a remainder of the sensors, and
the controller determines that the battery is abnormal when at least two sensors of the plurality of sensors output abnormal values.

2. The battery system according to claim 1, wherein when one sensor of the plurality of sensors outputs an abnormal value, the controller determines that the one sensor is abnormal.

3. The battery system according to claim 1, wherein the controller is disposed at a position to reduce an influence of an abnormality of the battery on the controller.

4. A detection method for detecting an abnormality of a battery system, wherein
the battery system includes
a battery, and
a plurality of sensors that each detect a parameter of the battery, and
an abnormality of a sensor of the plurality of sensors does not lead to an abnormality of a remainder of the sensors,
the detection method comprising determining that the battery is abnormal when at least two sensors of the plurality of sensors output abnormal values.
